(19) United States
(12) Patent Application Publication
(10) Pub. No.: US 2009/0302389 A1
(43) Pub. Date: Dec. 10, 2009

(54) METHOD OF MANUFACTURING SEMICONDUCTOR DEVICE WITH DIFFERENT METALLIC GATES

(75) Inventors: Robert Lander, Leuven (BE); Mark Van Dal, Heverlee (BE); Jacob Hooker, Kessel-Lo (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/066,707

(22) PCT Filed: Sep. 11, 2006
(86) PCT No.: PCT/IB2006/053205

§ 371 Date: Mar. 6, 2009

(30) Foreign Application Priority Data
Sep. 15, 2005 (EP) 05108495.2

(51) Int. Cl. H01L 27/092; H01L 21/8238

(52) U.S. Cl. 257/369; 438/233; 257/E27.062; 257/E21.636

(57) ABSTRACT

A method is described for forming gate structures with different metals on a single substrate. A thin semiconductor layer (26) is formed over gate dielectric (24) and patterned to be present in a first region (16) not a second region (18). Then, metal (30) is deposited and patterned to be present in the second region not the first. Then, a fully suicided gate process is carried out to result in a fully suicided gate structure in the first region and a gate structure in the second region including the fully suicided gate structure above the deposited metal (30).

The invention relates to a method of manufacturing a semiconductor device with two different gate materials, and a semiconductor device made by the method.

At present, most gates used in metal oxide semiconductor field effect transistor (MOSFET) type devices are polysilicon (poly). However, future MOSFETs may require the use of a metal gate electrode to eliminate poly-gate depletion effects, which are particularly prevalent with thin gate oxides.

However, the use of a metal gate electrode makes it difficult to achieve a low threshold voltage, since the work function of the metal is not readily matched to that of n−type or p−type silicon. The problem is particularly acute for CMOS circuits, which need gates with differing work functions for the nMOSFET and the PMOSFET devices.

A likely way of achieving CMOS metal gates is to use two different metals for the different gates. However, this requires patterning of one metal prior to deposition of the second metal. Such patterning can seriously impact the quality of the gate dielectric at the locations where the second metal is to be deposited, with a consequent deterioration in the quality of the device.

Removing the dielectric and reforming it in the presence of the first metal is generally undesirable, especially when carried out in an ultra-clean furnace.

An alternative approach is to use a fully silicided (FUSI) gate which has the advantage for dielectric quality that a metallic gate is formed for both NMOS and PMOS from a single deposited polysilicon layer. Unfortunately, such FUSI gates do not meet all the work function and material requirements for both PMOS and NMOS.

US-2004/0132271 describes a method of forming a pair of gates, one of polysilicon and one of silicide. In this process, a polysilicon layer is formed, a mask applied over one of the PMOS and NMOS regions, and then metal is deposited over the other of the PMOS and NMOS region, which remains exposed, and reacted with the polysilicon to form silicide. Then, the mask is removed, a polysilicon layer applied over the whole surface, and the result patterned to form a polysilicon gate in the region that was protected by the mask during the silicidation steps and a silicide gate in the region that was silicided.

A further approach is taught in US-2004/0099916. In this approach, a polysilicon layer is formed over the gate dielectric. A metal layer is then formed over the whole surface, and the metal layer is then patterned so that it is only present over one of the PMOS and NMOS transistor regions. Silicide is then formed over one of the regions, before the gates are patterned.

Neither of these processes forms two metallic gates, since one of the gates is polysilicon in both processes. Note that silicided gates will be referred to as metallic. The term “metal” will be used to refer to metal, metal alloy or doped metal layers; such layers are of course “metallic” as well as “metal”.

An alternative process which does provide two different gates of metal silicide is taught by U.S. Pat. No. 6,846,734 which forms fully silicided gates for both PMOS and NMOS transistors with different threshold voltages. Unfortunately, the process is very complicated, and both of the gates are of metal silicide—the process cannot be used to form a simple as—deposited metal gate.

There thus remains a need for an improved process for the manufacture of a pair of metallic gates.

According to the invention there is provided a method of manufacturing a semiconductor device, comprising the steps of:

depositing gate dielectric over the first major surface of a semiconductor body;

forming a deposited semiconductor cap over the gate dielectric in a first region of the semiconductor body leaving the gate dielectric exposed in a second region;

depositing a metal layer over the exposed gate dielectric in the second region and over the semiconductor cap in the first region;

etching away the metal layer in the first region;

depositing at least one precursor layer over the first and second regions;

patterning the at least one precursor layer and the metal layer to form a first gate pattern in the first region and a second gate pattern in the second region; and

carrying out a reaction of the precursor layer in the gate patterns forming in the first region a first gate of a reacted first metallic gate layer directly over the gate dielectric and in the second region a second gate including a reacted metallic gate layer above the metal layer above the gate dielectric.

The method delivers a pair of metallic gates. The invention delivers a transistor in which the gate layer adjacent to the gate dielectric is a reacted layer (such as a silicide) for one gate and a deposited metal layer for the other gate. Thus, any suitable choice of deposited metal thickness and material is possible for the deposited metal layer, allowing for great flexibility of manufacturing method.

By depositing the metal layer after the deposited semiconductor cap the dielectric in the first region is protected during the deposition of the metal to form the metal in contact with the dielectric in the second region. This greatly reduces the difficulties with dielectric quality with prior approaches.

One approach is to etch away the deposited semiconductor cap from the first region using a wet etch. This is significantly less damaging to the dielectric than etching techniques used to etch metals.

Alternatively, dry etching can be used if any damage caused is not significant.

Alternatively, the dielectric may be reformed after the selective removal of part of the deposited semiconductor cap. In this case, there are no contamination concerns which might occur when carrying out dielectric growth in the presence of a metal, since the metal has not been deposited yet.

Using the invention, the reaction forming the fully silicided layer is only carried out after the gate is patterned. This allows conventional gate patterning to be used. Such conventional gate patterning assumes polysilicon gates and can achieve very fine gate structures down to gate dimensions of 10 nm which is not generally available with other processes. Thus, it is in practice a big advantage not to form the fully silicided layer until the gate is patterned.

In preferred embodiments, the deposited semiconductor cap is of polysilicon. The thickness of the deposited semiconductor cap may be in the range 5 nm to 60 nm.

The at least one precursor layer may include a layer of polysilicon precursor and a sacrificial layer over the layer of polysilicon.

The reaction process may preferably be a self-aligned silicidation process, known as a salicidation process.

In one embodiment, the method includes the steps, after patterning the at least one precursor layer and the metal layer to form first and second gate patterns, of:

forming spacers on the sidewalls of the gate patterns;

forming a metal layer over the substrate; and

reacting the metal layer with the semiconductor body in the first and second regions to form source and drain contacts.

In this embodiment the method may further include, after forming the source and drain contacts:

depositing a planarising layer;

etching the planarising layer and the sacrificial layer back to form a planar surface exposing the polysilicon precursor; and

depositing a metal layer over the planar surface;

wherein the step of carrying out a reaction of the precursor layer includes reacting the metal layer with the polysilicon precursor to form a fully silicided gate.

In alternative embodiments, the method may include the steps, after patterning the at least one precursor layer and the metal layer to form first and second gate patterns, of:

forming spacers on the sidewalls of the gate patterns;

implanting the first major surface to form source and drain regions on either side of the gate patterns; and

removing the sacrifical layer.

In this embodiment, the method may further include, after removing the sacrificial cap:

forming a metal layer over the substrate; and

reacting the metal layer with the semiconductor body in the first and second regions to form gate contacts wherein this step of reacting the metal layer also reacts the metal layer with the polysilicon precursor to form a fully silicided gate to carry out the step of carrying out a reaction of the precursor layer.

In this way a single silicidation reaction carries out both the formation of the source and drain contacts and the fully silicided gates. This reduces the number of steps, and in particular avoids the need for a chemical mechanical polishing step.

In another aspect, the invention relates to a semiconductor device, comprising:

a semiconductor body;

a first region and a second region;

at least one transistor in the first region and at least one transistor in the second region, the transistors in the first and second regions having like gate dielectrics and like source and drain implants;

wherein the transistors in the first region has a fully silicided gate; and

the at least one transistor in the second region has a gate in the form of a fully silicided gate structure in like form to the fully silicided gate of the first structure above a metal layer.

The metal layer may be a deposited metal layer that can be freely chosen for thickness and material as discussed above.

The metal layer in the gate structure in the transistors of the second region may be, for example, of TiN, TaN, Ti, Co, W, or Ni.

For a better understanding of the invention, embodiments will now be described, purely by way of example, with reference to the accompanying drawings, in which:

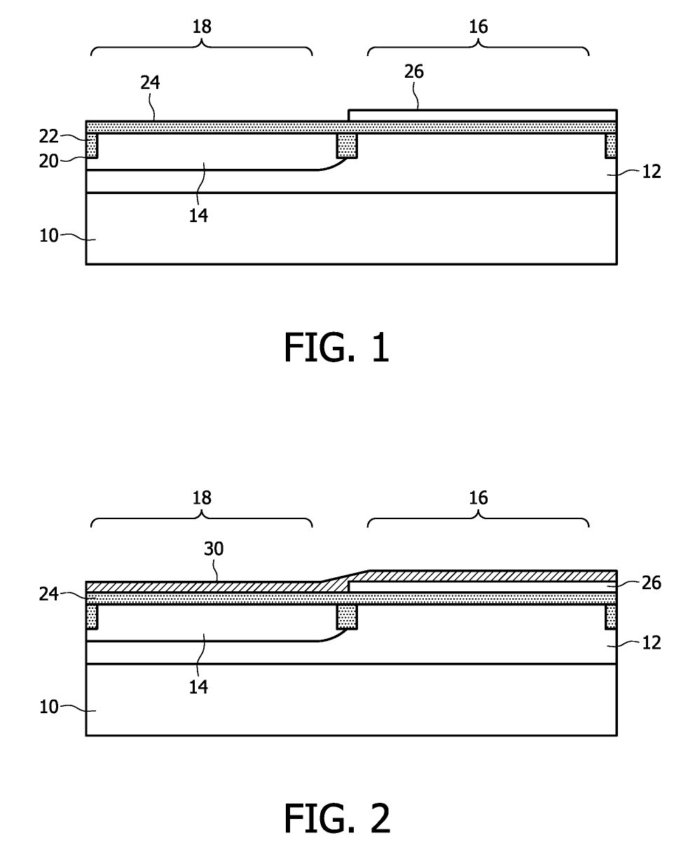

FIGS. 1 to 6 show steps of a method according to a first embodiment of the invention;

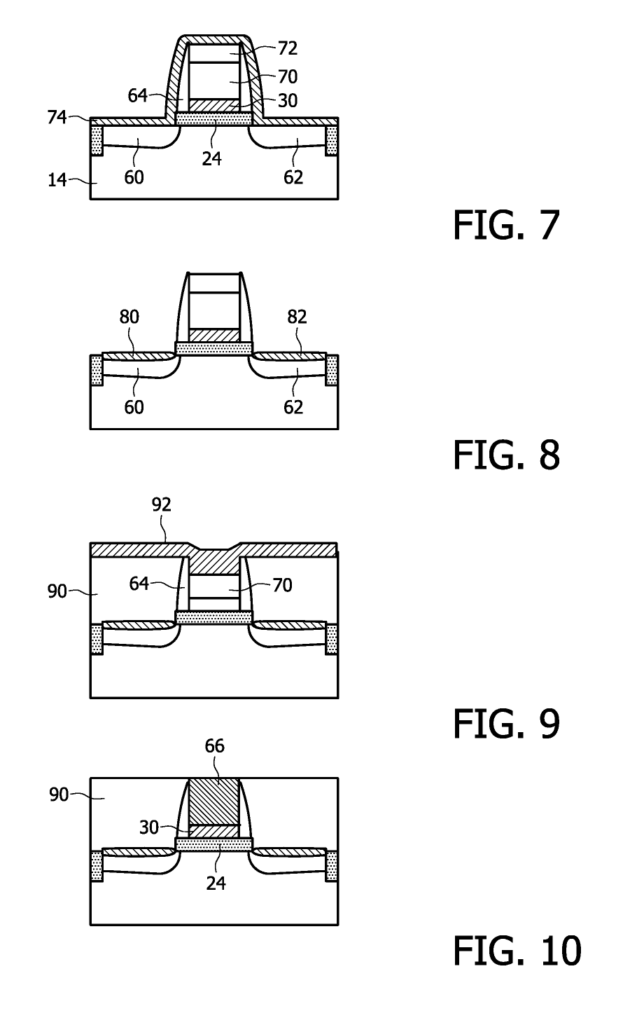

FIGS. 7 to 10 illustrate in detail sub-steps in the method of FIGS. 1 to 6;

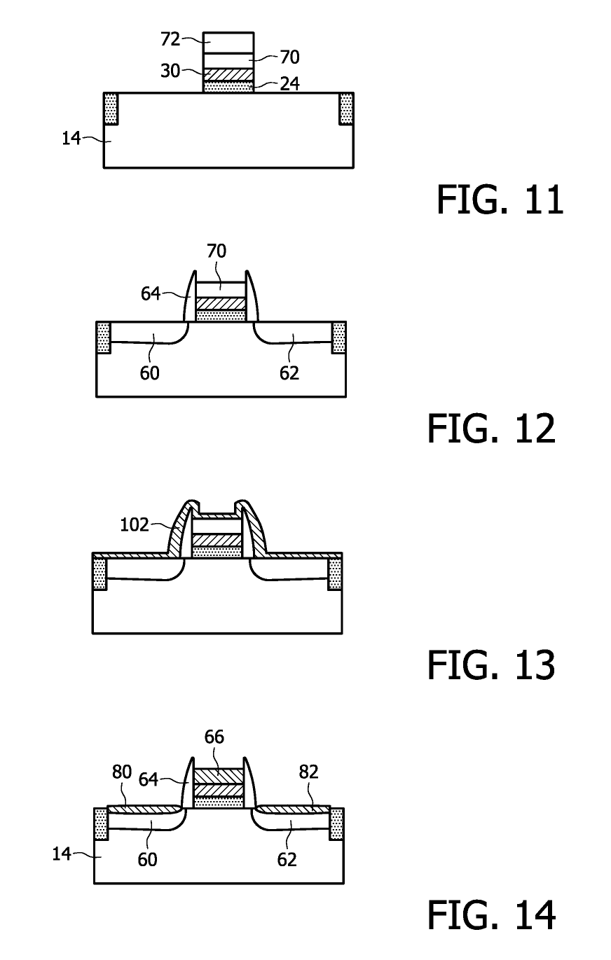

FIGS. 11 to 14 illustrate in detail sub-steps in a method according to a second embodiment of the invention.

Like or similar components are given the same reference numerals in the different figures.

Referring to FIGS. 1 to 6, a first embodiment of the method according to the invention uses an n+type substrate 10. An n−type epitaxial layer 12 is then formed and a p−type body diffusion 14 is implanted over part of the surface. The part of the surface that remains n−type will be referred to the first region 16 in the following and the part of the surface that is rendered p−type will be referred to as the second region 18. In the final structure, the first region 16 and the second region 18 are used to form complementary transistors.

Insulated trenches 20 are formed and filled with silicon dioxide 22 to separate the regions.

Next, a thin gate dielectric 24 of SiO₂ is grown over the whole of the surface, and a thin poly-silicon (poly) cap 26 is formed over the gate dielectric 24 in the first region 16 but not the second 18. Conveniently, the thickness of the thin cap 26 is at least 5 nm, to protect the dielectric from the etch used to etch away metal 30, but thin enough to avoid topographic issues for lithography, preferably having a thickness less than 50 nm, further preferably less than 20 nm. In the specific embodiment described the poly layer is 10 nm thick.

Preferably, the poly 26 may be patterned by photolithography in a manner known to those skilled in the art, for example by depositing the poly over the whole surface, defining a photolithographic pattern in photoresist over the first region, etching away the exposed poly in the second region, and stripping the resist.

In the embodiment, the poly is etched away using a wet etch which causes reduced damage to gate dielectric 24.

In an alternative embodiment (not shown), the gate dielectric 24 in the first region is removed and reformed during these steps.

In either approach, this results in the structure shown in FIG. 1.

Next, a metal layer 30 is deposited over the whole surface. A hard mask can also optionally be deposited at this stage if required for the subsequent steps.

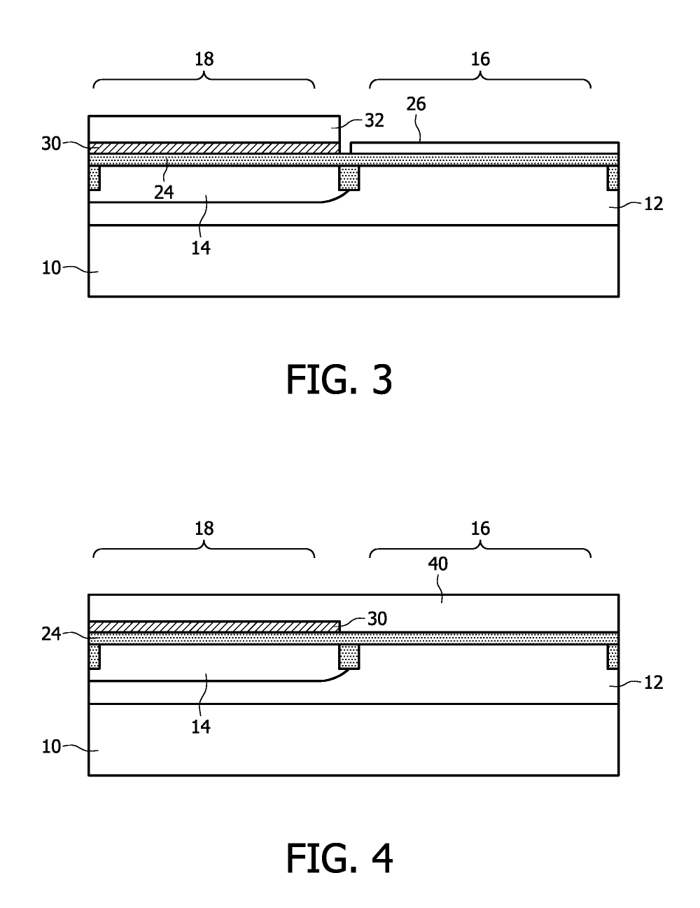

Photoresist 32 is then formed and patterned in the second region 18 and the metal layer 30 removed in the regions without photoresist, namely first region 16, leaving the metal layer 30 in the second region 18 as shown in FIG. 3.

The photoresist 32 is removed and a stack of layers 40 deposited over the surface, resulting in the structure of FIG. 4. The stack of layers 40 is selected to be able to form a fully silicided gate and suitable materials for the stack will be described later.

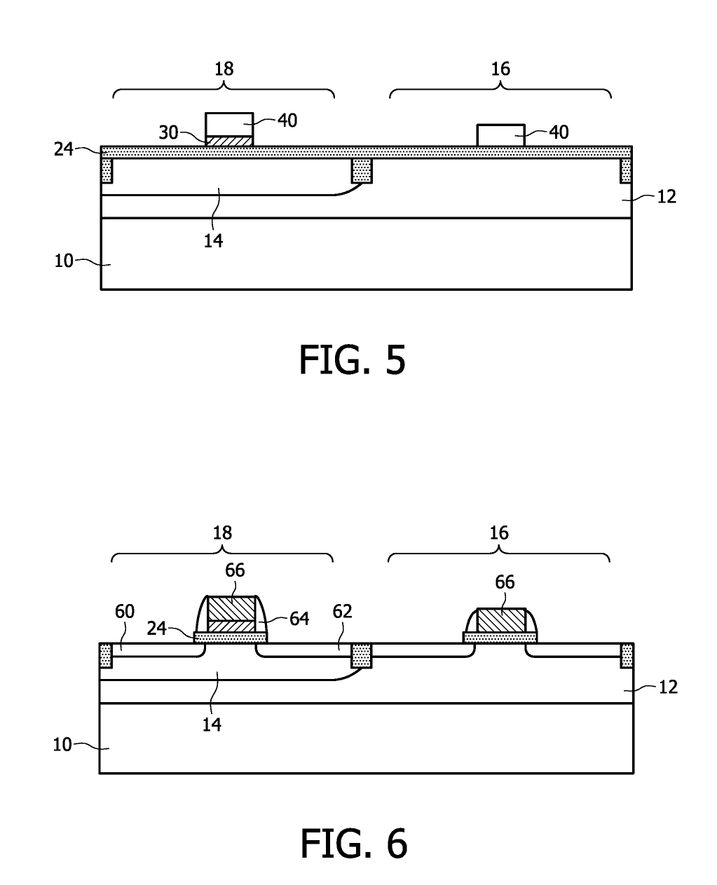

Next, a single patterning step is used to define the gates in both the first and second regions. The etch step removes both metal layer 30 and the stack of layers 40 in the second region 18 and the stack of layers 40 in the first region. The etch is selected to stop on the dielectric, as illustrated in FIG. 5.

Since the silicidation reaction has not yet taken place, conventional gate patterning may be used which is designed to etch poly. It is a significant benefit of the invention that such conventional gate patterning is possible, since such patterning is highly optimised to reliably produce very small features.

Finally, the gate dielectric is removed except under the gate, implantation is carried out to form source and drain regions 60, 62, spacers 64 are formed on the sidewalls of the metal layer 30 (where present) and the stack of layers (40), and processing is carried out to turn the stack of layers into a fully silicided gate 66. Note that the fully silicided gate refers to the process—it will be seen that the gate in the second region 18 has in addition the deposited metal layer 30 remaining.

This leads to the device as illustrated in FIG. 6. Note that the device is then finished as is known to those skilled in the art, by adding contacts, gate, source and drain metallisations, etc.

Any suitable silicidation process may be used to form the fully silicided gate 66—as will be appreciated the chosen process will determine the required layers. Suitable processes will now be discussed.

FIGS. 7 to 10 illustrate a first approach that may be used. Note that these figures show the process in the second region 18 in which metal layer 30 is present. The same process occurs in the first region 16 except that in that region the metal layer 30 is absent.

As shown in FIG. 7, the stack in this case includes a layer of polysilicon 70 followed by a sacrificial cap 72 made for example of silicon dioxide (SiO₂ or SiGe (20% Si, 80% Ge). A 50% Si 50% Ge layer may be used alternatively or additionally—such a layer may be selectively removed by an APM (ammonia—peroxide mixture) wet etch.

After patterning the stack, sidewall spacers 64 are formed on the sidewalls of the metal layer 30, polysilicon 70 and sacrifical cap 72, removing the gate dielectric 24 except under the stack 30,70,72 and the spacers 64.

Source and drain implantation is carried out to form source and drain regions 60,62 adjacent to the spacers. Since in this structure, the body of the transistor is the p−type region 14, in this case the source and drain implantations 60,62 are n−type. In n−type region 12, p−type implantations may be used.

Then, a metal layer 74 is deposited over the full surface leading to the structure of FIG. 7.

Next, the device is annealed to react the metal layer 74 with the source and drain regions 60, 62 to form source contact 80 and drain contact 82 regions of silicide. A selective etch is then used to remove the metal layer 74 where it has not reacted resulting in the structure of FIG. 8. Thus, the approach is a self-aligned silicidation process, i.e. a salicidation process.

A planarisation layer 90 is then formed and chemical mechanical polishing used to etch the structure back, removing sacrificial cap 72 and the top of the spacers 64. A layer 92 of siliciding metal is then deposited over the full surface as illustrated in FIG. 9.

The silicidation reaction is then carried out to fully react all the polysilicon 70 with metal 92 to form fully silicided gate 66. The remaining metal 92 is then selectively etched leaving the structure of FIG. 10.

Note that the structure has a fully silicided layer 66 above a metal layer 30. Thus, the transistor in the second region retains the as-deposited metal 30 as determining the properties of the gate. This allows a metal to be selected based on its required properties rather than compatibility with the process.

Returning to FIG. 6, it may be seen that in the second region the metal 30 is above the gate dielectric but in the first region it is the fully silicided region. Thus using the method according to the invention it is straightforward to provide one gate having properties determined by deposited metal layer 30 and the other gate fully silicided.

An alternative embodiment is illustrated in FIGS. 11 to 14. This is the same as the first embodiment except for the processing of the stack to form transistors. In the second embodiment, the process steps described with reference to FIGS. 7 to 10 of the first embodiment are replaced with those described with reference to FIGS. 11 to 14.

In the approach of the second embodiment, a much thinner layer of poly 70 is used as part of a stack that again includes a sacrifical cap 72. The stack is illustrated in FIG. 11. The thickness of the poly layer 70 is similar to that consumed in the source and drain regions 60,62 during the subsequent silicidation, for example 20 nm. A suitable choice of layer thicknesses for poly 70 is 5 to 30 nm.

An alternative approach grows epitaxial silicon on the source and drain which allows a greater thickness of poly 70 to be used, in the range 5 nm to 50 nm.

Then, spacers 64 are formed, implantation carried out to from source and drain regions 60, 62 in the body region 14 and the sacrificial cap removed (FIG. 12).

A single layer of siliciding metal 102 is then deposited over the full surface, as shown in FIG. 13. A siliciding reaction carried out to form silicide source and drain contact regions 80, 78 in the source and drain regions 60, 62 at the same time as a silicide gate 66. A selective etch is then carried out to remove the unreacted metal 102 leaving the structure of FIG. 14.

It will be seen that this alternative embodiment has the advantage of omitting the need to planarise the surface and then carry out a chemical mechanical polish, and further only one siliciding step is used to form both the source and drain contacts 70,72 as well as fully silicided gate 110.

Those skilled in the art will realise that there are many alternatives that may be used. Any suitable materials may be used, either for the metals or the semiconductors. For example, some of the silicon layers may be replaced with germanium which also reacts with metal and in this case the gate may be a fully germanised gate not a fully silicided gate.

The choice of metal used to silicide (or germanise) the gate may be selected as required. For example, Co, Ni, Ti, W, Yb, Er, Mo, Ta and their alloys may all be used.

Although in the embodiment described the stack includes polysilicon and a sacrifical cap, other materials may be used. For example, the polysilicon may be replaced with germanium, leading to a fully germanided gate. Alternatively, a multiple layer of polysilicon and germanium may be used, leading to a metal silicide germanide gate, e.g. NiSiGe.

The method is not restricted to making CMOS transistors but may be used wherever there is a need for two separate gate materials for different transistors.

1. A method of manufacturing a semiconductor device, comprising the steps of:
depositing gate dielectric over the first major surface of a semiconductor body;
forming a deposited semiconductor cap over the gate dielectric in a first region of the semiconductor body leaving the gate dielectric exposed in a second region;
depositing a metal layer over the exposed gate dielectric in the second region and over the semiconductor cap in the first region;
etching away the metal layer in the first region;
depositing at least one precursor layer over the first and second regions;
patterning the at least one precursor layer and the metal layer to form a first gate pattern in the first region and a second gate pattern in the second region; and
carrying out a reaction of the precursor layer in the gate patterns forming in the first region a first gate of a reacted first metallic gate layer directly over the gate dielectric and in the second region a second gate including a reacted metallic gate layer above the metal layer above the gate dielectric.

2. A method according to claim 1 wherein the deposited semiconductor cap is of polysilicon.

3. A method according to claim 1 wherein the thickness of the deposited semiconductor cap is in the range 5 nm to 20 nm.

4. A method according to claim 1 wherein the reaction fully reacts the semiconductor cap.

5. A method according to claim 1 wherein the at least one precursor layer includes a layer of polysilicon precursor and a sacrificial layer over the layer of polysilicon precursor.

6. A method according to claim 5, including the steps, after patterning the at least one polysilicon precursor layer and the metal layer to form first and second gate patterns, of:
forming spacers on the sidewalls of the gate patterns;
forming a metal layer over the first and second regions; and
reacting the metal layer with the semiconductor body in the first and second regions to form gate contacts.

7. A method according to claim 6, further comprising, after forming the gate contacts:
depositing a planarising layer;
etching the planarising layer and the sacrificial layer back to form a surface exposing the polysilicon precursor; and
depositing a metal layer over the surface;
wherein the step of carrying out a reaction of the precursor layer includes reacting the metal layer with the polysilicon precursor to form a fully silicided gate.

8. A method according to claim 5, including the steps, after patterning the at least one precursor layer and the metal layer to form first and second gate patterns, of forming spacers on the sidewalls of the gate patterns;
implanting the first major surface to form source and drain regions on either side of the gate patterns; and removing the sacrificial layer.

9. A method according to claim 8, further comprising, after removing the sacrificial layer:
forming a metal layer over the first and second regions; and
reacting the metal layer with the semiconductor body in the first and second regions to form source and drain contacts wherein this step of reacting the metal layer also reacts the metal layer with the polysilicon precursor to form a fully silicided gate.

10. A semiconductor device, comprising
a semiconductor;
a first region and a second region;
at least one transistor in the first region and at least one transistor in the second region, the transistors in the first and second regions having like gate dielectrics, like source and drain regions and like source and drain contacts;
wherein the at least one transistor in the first region has a fully silicided gate; and the at least one transistor in the second region has a gate in the form of a fully silicided gate structure in like form to the fully silicided gate of the first structure above a metal layer.

11. A semiconductor device according to claim 10 wherein the metal layer in the gate structure in the transistors of the second region is of TiN, TaN, Ti, Co, W, or Ni.
